(19) United States
(12) Patent Application Publication
(10) Pub. No.: US 2019/0206777 A1
(43) Pub. Date: Jul. 4, 2019

(54) INTERPOSER WITH ANGLED VIAS

(71) Applicant: Intel IP Corporation, Santa Clara, CA (US)

(72) Inventors: Sonja Koller, Regensburg (DE); Lizabeth Keser, Munich (DE); Bernd Waidhas, Pettendorf (DE); Georg Seidmann, Landshut (DE)

(21) Appl. No.: 15/857,207

(22) Filed: Dec. 28, 2017

(51) Int. Cl. H01L 23/498; H01L 21/48; H05K 3/40

(52) U.S. Cl. CPC H01L 23/49822; H01L 23/49816; H01L 21/486; H05K 2201/095; H05K 3/4007; H05K 2201/10378; H01L 21/4857

(57) ABSTRACT

An interposer for an electronic package including at least one angled via. The interposer can include a dielectric layer including a first surface and a second surface. The dielectric layer can include a normal axis perpendicular with the first or second surface. In an example, an angled via can include a first end located along the first surface and a second end located along the second surface. A longitudinal axis of the angled via can be extended between the first end and the second end. The longitudinal axis is disposed at an angle from the normal axis to form an angled via.

### TECHNICAL FIELD

This document pertains generally, but not by way of limitation, to electronic packaging, such as electronic packaging of semiconductors.

### BACKGROUND

Laminated interposers can accommodate a difference in pitch between interconnects of a die (or a packaged die) and corresponding interconnects of a circuit board. In some instances, the interconnects of the circuit board can have a larger pitch than the interconnects of the die. The larger pitch of the circuit board can provide for increased robustness of the board interconnects and decreased tolerance requirements for interconnect placement or manufacture. For example, in the pitch of the die interconnects can be 100 micrometers or less. The pitch of the board interconnects, on the other hand, can be 100 micrometers or greater. Laminate interposers are often constructed using multiple layers of foil and dielectric to form the routing structure between a first and second side of the laminate interposer. The one or more routing structures can be provided to electrically couple the die interconnect with the board interconnect where a first end of the routing structure is misaligned with a second end of the signal routing structure along a normal axis of the laminate interposer. An interposer having fewer production steps and fewer layers is desirable.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example of an electronic device including a die coupled to a circuit board with an interposer, according to an embodiment.

FIG. 2 is a cross section view of an example of an interposer including a plurality of angled vias, according to an embodiment.

FIG. 3A illustrates an upper view of an example of an interposer including a plurality of angled vias arranged in a first pattern, according to an embodiment.

FIG. 3B illustrates a lower view of an example of an interposer including a plurality of angled vias arranged in a second pattern, according to an embodiment.

FIG. 4A depicts an upper view of another example of an interposer including a plurality of angled vias arranged in another first pattern, according to an embodiment.

FIG. 4B illustrates a lower view of another example of an interposer including a plurality of angled vias arranged in another second pattern, according to an embodiment.

FIG. 5 depicts an upper view of an example of an interposer including a solder pad, according to an embodiment.

FIG. 6 is block diagram of an exemplary method for making an interposer having at least one angled via, according to an embodiment.

FIG. 7 illustrates a system level diagram in accordance with some embodiments of the invention.

### DETAILED DESCRIPTION

The present application relates to devices and techniques for an interposer, such as an interposer including at least one angled via. The following detailed description and examples are illustrative of the subject matter disclosed herein: however, the subject matter disclosed is not limited to the following description and examples provided. Portions and features of some embodiments may be included in, or substituted for, those of other embodiments. Embodiments set forth in the claims encompass all available equivalents of those claims.

The present inventors have recognized, among other technical challenges, that using a laminated interposer to accommodate a difference in pitch between the interconnects of a die (or die package) and corresponding interconnects of a circuit board can increase the cost, size, and complexity of an electronic package or electronic device. Circuit boards can include, but are not limited to, substrates, printed circuit boards, or other signal routing structures. The interconnects of the circuit board (board interconnects) can have a larger pitch than those of the die (die interconnects). The larger pitch of the circuit board can provide for increased robustness of the board interconnects and decreased tolerance requirements. In some examples, the circuit board can be constructed utilizing lower cost production equipment and techniques. However, advances in semiconductor fabrication and demand for increased computing performance are driving decreases in the pitch of the die interconnects. For example, the pitch of the die interconnects can be 100 micrometers or less. The pitch of the board interconnects, on the other hand, can be 100 micrometers or greater. Interposers can be used to accommodate the disparity in interconnect pitch (i.e., the difference between the pitch of the die interconnects and the pitch of the board interconnects). For instance, one or more signal routing structures can be provided to electrically couple the die interconnect with the board interconnect where a first end of the signal routing structure is misaligned with a second end of the signal routing structure along a normal axis of the laminate interposer (e.g., vertically).

However, laminate interposers are often constructed using multiple layers of foil and dielectric to form the routing structure between a first and second side of the laminate interposer. Fabrication of the laminate interposer can include a plurality of steps including, but not limited to, lamination, metallization, masking, etching, and cleaning. Accordingly, the routing structure can be located along (e.g., parallel with) the first and second surfaces of the interposer and electrically coupled by a via extending perpendicular (e.g., normal) to the first and second surfaces. Correspondingly, the laminate interposer can include complex geometry that can be costly and time consuming to fabricate.

The present subject matter can provide a solution to one or more of these technical challenges by, for example, providing an interposer including at least one angled via, such as a via having a longitudinal axis that is different than a normal axis of the interposer. For example, the interposer can include a dielectric layer having a first surface and a second surface. The normal axis of the dielectric layer can be perpendicular with the first, second surface, or both. The angled via can extend between a first end located along the first surface and a second end located along the second surface. A longitudinal axis of the angled via can extend between the first end and the second end, and can be disposed at an angle from the normal axis. Accordingly, the angled via can electrically couple an interconnect of a die (die interconnect) to an interconnect of a circuit board (board interconnect) where the die interconnect is not aligned with the board interconnect along a normal axis of the interposer. For instance, the die can include a plurality of die interconnects and the circuit board can include a plurality of board interconnects.

In some examples, the die interconnects can be arranged in a first pattern having a first pitch and the board interconnects can be arranged in a second pattern having a different pitch than the die interconnects. The plurality of angled vias can communicatively couple the die interconnects of the first pattern to the respective board interconnects of the second pattern. With the angled vias, the interposer can electrically couple the die interconnects with the respective board interconnects using a single layer construction. In other words, the first end of each angled via can be positioned at the location of the corresponding die interconnect and the second end of the angled via can be positioned at the corresponding location of the respective board interconnect without requiring a routing layer or solder pad along the first or second surface of the interposer. Accordingly, providing an angled via in the interposer can reduce the amount of material and the number of pieces or layers used in the interposer. The number of process steps to construct the interposer can also be reduced as compared to laminated interposers. Correspondingly, the cost and time for constructing the interposer can be reduced.

In an example, area of the first surface between the respective first ends or area of the second surface between the respective second ends of the angled vias can be used for additional signal routing. Because the angled vias extend along the respective longitudinal axes (e.g., linearly), the distance of the electrical connection between the die interconnects and the board interconnects can be reduced as compared to the construction of laminated interposers having electrical connections with vias along the normal axis and routing layers oriented ninety-degrees from the normal axis along the first and second surfaces. For instance, the angled vias can be disposed along the shortest path between the die interconnects and the board interconnects.

The electrical connections of laminated interposers can have some degree of impedance mismatch based on changes in the cross-sectional area between the via portion extending along the normal axis and the routing layer portion extending along the first or second surfaces of the dielectric layer. However, the angle vias of the present disclosure can mitigate the impedance mismatch by providing an electrical connection having a similar cross section between the first and the second ends (or between the die interconnects and the board interconnects). In other examples, the first or second end of the respective angled vias can be sized or shaped to correspond with the respective die interconnects and board interconnects, without requiring a solder pad.

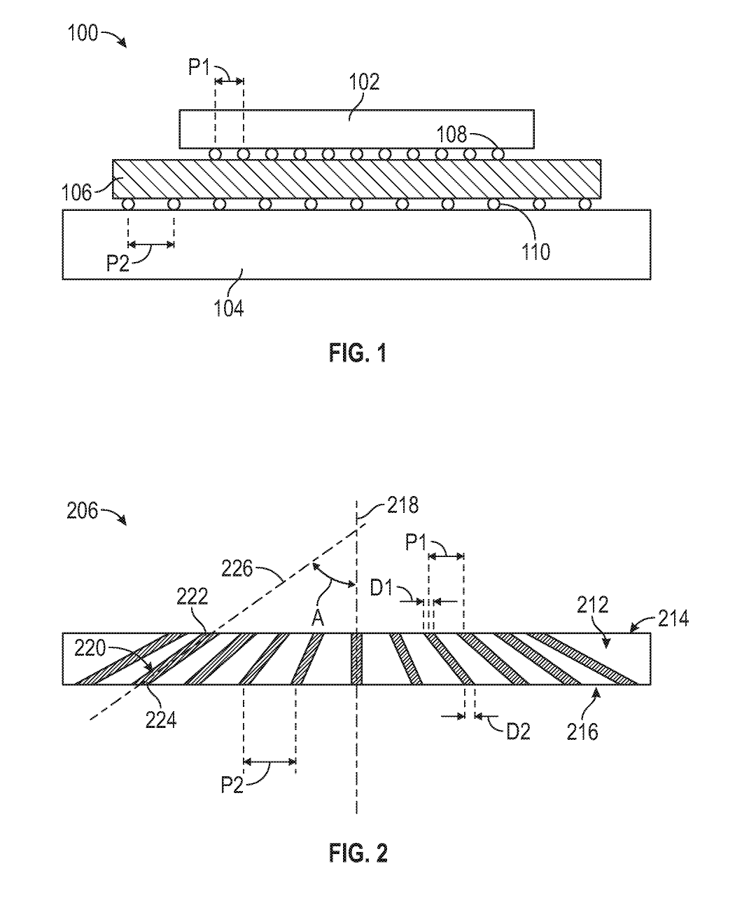

FIG. 1 illustrates an example of an electronic device 100 including a die 102 communicatively coupled to a circuit board 104 of an electronic device with an interposer 106. The die 102 can include, but is not limited to, a processor (e.g., graphics processing unit [GPU] or central processing unit [CPU]), memory package (e.g., random access memory [RAM], flash memory, read only memory [ROM]), or other logic or memory package. As discussed herein, the die 102 can be a bare die or a packaged die. In the example of FIG. 1, the die 102 can be electrically coupled to the interposer 106 with a plurality of interconnects 108 (also referred to herein as die interconnects). The interposer 106 can be electrically coupled to the circuit board 104 through a plurality of interconnects 110 (also referred to herein as board interconnects). The circuit board 104, can include, but is not limited to, a printed circuit board, substrate, flexible circuit, printed wiring board, ceramic substrate core, or other signal routing structure. Accordingly, the interposer 106 can communicatively couple the die 102 to the circuit board 104 through the interposer 106 and the plurality of die interconnects 108 and corresponding board interconnects 110. As discussed herein, the corresponding board interconnects 110 can be electrically coupled to respective die interconnects 108 through the interposer 106.

In some examples, the die interconnects 108 or the board interconnects 110 can include, but are not limited to, conductive pillars, solder balls, ball grid array, land grid array, flip chip controlled collapse chip connection (c4), or the like. In some instances, the pitch between one or more of the die interconnects 108 can be different than a pitch between one or more of the board interconnects 110. As shown in the example of FIG. 1, a pitch P1 between the plurality of die interconnects 108 can be different than a pitch P2 between the plurality of board interconnects 110. For instance, the pitch P1 can be 100 micrometers or less and the pitch P2 can be 100 micrometers, 500 micrometers, 1 millimeter, two millimeters, or any value therebetween. In other examples, the pitch P1 can be the same as the pitch P2. Other pitch values are also contemplated, and the pitch of the die interconnects or the board interconnects are not limited to the values described in the examples herein. In some examples, the die interconnects 108 can be arranged in a different pattern or location along the interposer than the corresponding board interconnects 110.

FIG. 2 is a cross section view of an example of an interposer 206 including at least one angled via, such as a plurality of angled vias 220. The interposer 206 can include a dielectric layer 212 having a first surface 214 and a second surface 216. The dielectric layer 212 can include a normal axis 218 that is perpendicular with the first surface 214, the second surface 216, or both. In some examples, the normal axis 218 can also be the normal axis of the interposer, as shown in the example of FIG. 2. The dielectric layer can include, but is not limited to, mold compound, FR4, polyimide, epoxy, glass-epoxy composite, other epoxy composite or polymer composite, ceramic, or other dielectric materials. In an example, the interposer can include a single layer, for instance, a single dielectric layer 212, as shown in the example of FIG. 2. Accordingly, the amount of material and the number of pieces or layers used in the construction of the interposer 206 can be reduced. The number of process steps to construct the interposer 206 can also be reduced as compared to laminated interposers. Correspondingly, the cost and time for constructing the interposer 206 can be reduced. In other examples, the interposer can include a plurality of layers, such as a plurality of dielectric layers, solder masking layers, routing layers, or combinations thereof.

The at least one angled via 220 can extend between a first end 222 located along the first surface 214 and a second end 224 located along the second surface 216. In some examples, the angled via 220 can be extended through a plurality of dielectric layers. The angled via 220 can include an electrically conductive material for communicatively coupling a die (e.g., the die 102 as shown in FIG. 1) to a circuit board (e.g., circuit board 104) using a first interconnect and a second interconnect, such as first interconnect 108 or second interconnect 110 of the example of FIG. 1. The angled via 220 can be constructed from a conductive material including, but not limited to, copper, tin, silver, gold, or other conductive materials or alloys. In some examples, the angled via 200 can be a solid between the first end 222 and the second end 224. While in other examples, the angled via 220 can include a void or a lumen extended therethrough, for instance, the angled via 220 can be a plated through-hole (e.g., a conformal coating of an aperture through the dielectric layer).

A longitudinal axis 226 of the angled via 220 can be extended between the first end 222 and the second end 224. The longitudinal axis 226 can be disposed at an angle A from the normal axis 218. As used herein, disposed at the angle A refers to an angle that is greater than zero, but less than ninety degrees. In some examples, the angle A can be 5, 10, 20, 30, 40, 50 degrees or an angle therebetween. In another example, the angle A can be an angle between 1 and 89 degrees. Accordingly, the angled via 220 can electrically couple the die interconnect 108 to the board interconnect 110 where the die interconnect 108 is disposed at an angle (non-zero angle) with the board interconnect 110 along the normal axis 218 of the interposer 206. For instance, as shown in FIG. 2, the plurality of angled vias 220 can include the first pitch P1 at the first end 222 and the second pitch P2 at the second end 224. The angled vias 220 can extend (e.g., linearly) between the respective first ends 222 and the second ends 224, for instance, along the shortest path between the respective first ends 222 and the second ends 224.

In the example of FIG. 2, the longitudinal axes of the plurality of vias 220 can be disposed at the same or different angles from the normal axis 218. For instance, the interposer can include at least a first angled via and a second angled via. A longitudinal axis of the first angled via can be disposed at a first angle from the normal axis, and a longitudinal axis of the second angled via can be disposed at a second angle with respect to the normal axis. The first angle can be different than the second angle. In some examples, as shown in FIG. 2, the angle of the respective angled vias can increase or decrease along a length (e.g., x-axis) of the interposer 206. For instance, the longitudinal angles of the respective angled vias near the center of the interposer can be smaller than the angles of the longitudinal axes of the vias closer to the perimeter of the interposer.

The first end 222 or the second end 224 can be used as a solder pad to electrically couple the respective die interconnects 108 to the board interconnects 110. The first end 222 or the second end 224 can be sized and shaped for soldering or otherwise electrically coupling the angled via 220 to the respective die interconnect 108 or board interconnect 110. In some examples, the first end 222 can include a first cross-sectional dimension D1, and the second end can include a cross-sectional dimension D2. The cross-sectional dimensions D1 and D1 can be the dimension of the first end 122 or the second end 124 as measured in a direction along the first surface 114 or the second surface 116 respectively. Where the die interconnect 108 is a different shape or size than the board interconnect 110, the dimension D1 can be correspondingly different than the dimension D2. For instance, the dimension D1 can be smaller than the dimension D2 for coupling the smaller or finer pitched die interconnects 110 to the larger sized or pitched board interconnects 110. For example, where the angled via 220 has a circular cross-sectional shape perpendicular to the longitudinal axis 226, the angled via 220 can have a conical shape to adapt the smaller diameter D1 of the first end 222 to the larger diameter D2 of the second end 224. In other examples, the angled via 220 can include an hourglass shape with the diameters D1 and D2 being larger than the smallest diameter of the angled via 220. In the example of FIG. 2, the dimension D1 can be the same size as the dimension D2. In other examples, the dimension D2 can be greater than the dimension D1, or vice versa. For instance, the dimension D2 can be 1.1, 1.25, 1.5, 2 times larger than dimension D1, or any value therebetween, or the other way around. In further examples, the dimension D2 can be between 1.25 and 5 times larger than the dimension D1, or vice versa. In some examples, the dimension D2 can be up to 25 times larger than the dimension D1, or the other way around. Accordingly, the interposer 206 constructed of a single layer can electrically couple the die 102 to the circuit board 104, for instance, without requiring a routing layer or solder pad along the first or second surface of the interposer 206.

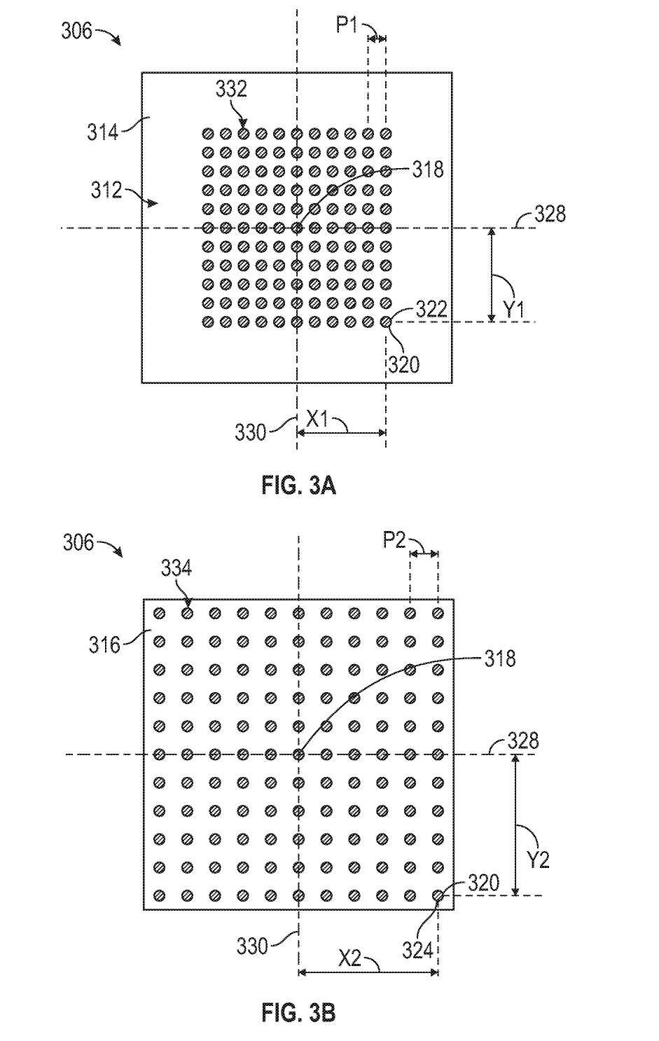

FIG. 3A illustrates a top view of an example of an interposer 306 including a plurality of angled vias 320. A plurality of first ends 322 can be arranged along a first surface 314 of a dielectric layer 312. In the example, of FIGS. 3A and 3B the plurality of angled vias 320 can be arranged in a first pattern 332, such as a grid pattern. Other patterns are contemplated, such as circular patterns, staggered patterns, diamond patterns, irregular patterns, or other arrangements of the first ends 322 along the first surface 314. FIG. 3B illustrates a lower view of an example of the interposer 306 including a second end 324 of the plurality of angled vias 320. The second ends 324 can be arranged along the second surface 316. For instance, the second ends 324 can be arranged in a second pattern 334. As shown in the example of FIG. 3B, the second pattern 334 can be similar to the first pattern 332. The difference between the first pattern 332 and the second pattern 334 is that the first pattern 332 can have a different pitch (e.g., P1) than the pitch (e.g., P2) of the second pattern 334. In some examples, the center of the first pattern 332 and the center of the second pattern 334 can be aligned along the normal axis of the interposer 306, as shown in the examples of FIGS. 3A and 3B.

The angled vias 320 can have a cross-sectional shape, such as a circular, rectangular, triangular, or other geometrical shape. In the example of FIGS. 3A and 3B the angled vias 320 can have a circular cross-sectional shape. In some examples, the first end 322 and second end 324 can include the same or different cross-sectional shapes.

As shown in the example of FIGS. 3A and 3B, the plurality of first ends 322 can have different locations along an x-axis 328 or a y-axis 330 than the location of the second end 324 along the x-axis 328 or the y-axis 330. The x-axis 328 and y-axis 330 are orthogonal to a normal axis 318. For instance, the first end 322 can have a first location X1 along the x-axis 328 and a first location Y1 along the y-axis 330. The second end 324 can have a second location X2 along the x-axis 328 and a second location Y2 along the y-axis 330. In some examples, the location X1 and Y1 can be different than the location of X2 and Y2, as depicted in FIGS. 3A and 3B.

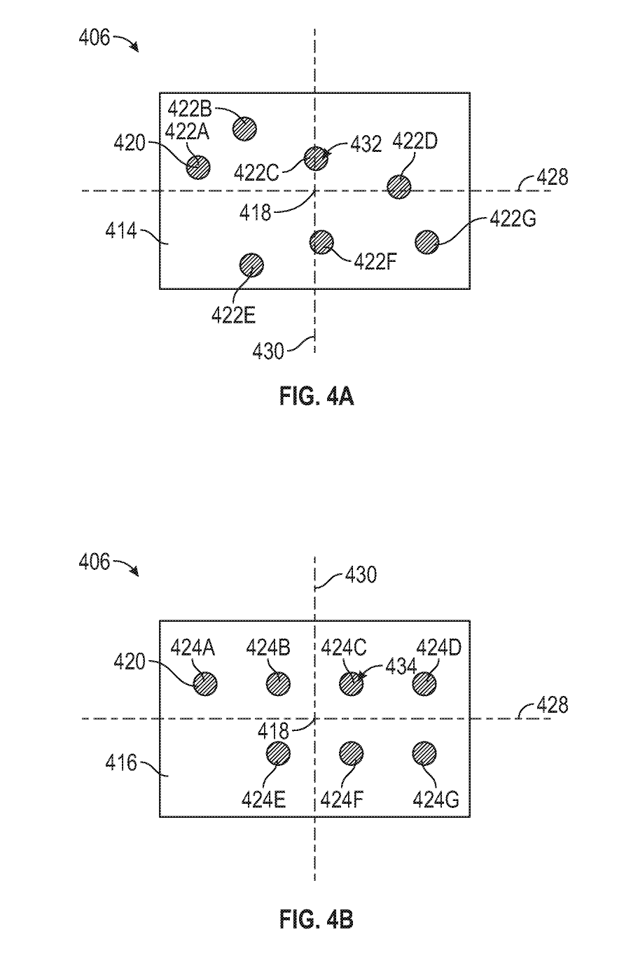

FIG. 4A depicts an example of an upper view of an interposer 406 including a plurality of angled vias 420 arranged in a first pattern 432 along a first surface 414. The angled vias 420 can include respective first ends 422A-G and a second end 424A-G. FIG. 4B illustrates the respective second ends 424A-G arranged in a second pattern 434 along a second surface 416. As previously described, the angled vias 420 can extend (e.g., linearly) between the respective first ends 422A-G and the second ends 424A-G, for instance, along the shortest path between the respective first ends 422A-G and the second ends 424A-G. The first pattern 432 can be different than the second pattern 434. For instance, the second pattern 434 can have a different relative position between the respective first ends 422A-G and the second ends 424A-G, such as a different arrangement of the respective first ends 422A-G and the second ends 424A-G. In the example of FIG. 4A, the pattern 432 can have an irregular arrangement of the first ends 422A-G and the pattern 424A-G can have a grid pattern. In some examples, the angles (such as angles A shown in the example of FIG. 2) of one or more of the respective angular vias 420 can be different with respect to a normal axis 418. For instance, in the example of FIGS. 4A-4B, each of the angles of the respective angled vias 420 can be different. Accordingly, the angled vias 420 can electrically couple one or more first ends with second ends that are disposed at an angle from the normal axis with respect to the corresponding first ends. Thus, the first ends can be electrically coupled to the second ends without routing layers along the first surface or the second surface of the dielectric layer.

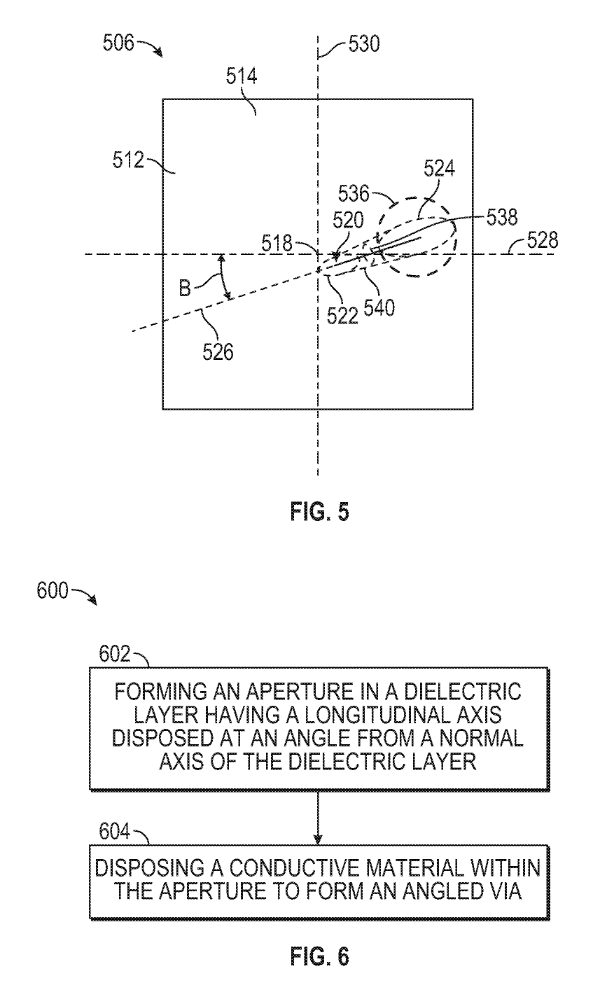

FIG. 5 depicts an upper view of an example of an interposer 506 including a solder pad 536. The solder pad 536 can be disposed on a first end (e.g., 522) or a second end (e.g., 524) of an angled via 520. For instance, in the example of FIG. 5, the solder pad 536 can be disposed on the second end 524. The angled via 520 can be constructed by forming an aperture 540 between a first surface 514 and a second surface of a dielectric layer 512. In some examples, a laser beam can trace a profile to produce a cross-sectional shape 538 of the aperture 540. The cross-sectional shape 538 can be perpendicular to the longitudinal axis 526, and can include, but is not limited to, a circular, rectangular, triangular, or other geometrical cross-sectional shape 538. In various examples, the aperture 540 can be formed using a fixed laser beam or mechanical drilling operation. The angled via 520 can include a conductive material filling the aperture 540. Where the aperture 540 can have a circular cross-sectional shape 538 along the longitudinal axis 526, the first end 522 or the second end 524 can include an oval shape along the first surface 514 or the second surface respectively, as shown in the example of FIG. 5. As used herein, the oval shape can include an ellipse where a dimension of a major axis is different than a dimension of a minor axis. In an example where the angled via 520 has a circular cross-sectional shape 538 along the longitudinal axis 526, the first end 522 and the second end 524 can have an oval shape based on a projection of the circular cross-sectional shape 538 along the first surface 514 or the second surface. The projection of the circular cross-sectional shape 538 can produce various transformations of the cross-sectional shape 538 based on the angle (e.g., angle A) of the longitudinal axis 526 with respect to the normal axis 518.

The solder pad 536 can provide a circular contact (or other shape, such as rectangular) for coupling the angled via 520 to an interconnect, such as the die interconnect or board interconnect (e.g., the die interconnect 508 or the board interconnect 510). In an example, the solder pad 536 can have a different size or shape than the first end 522 or the second end 524 of the angled via 520. For instance, the solder pad 536 can be sized and shaped to be compatible with electrically coupling the angled via 520 with the die interconnect or board interconnect. For example, the die or board interconnect can be a solder ball or conductive pillar configured to be soldered to a round solder pad, such as the solder pad 536. Where the first end 522 or the second end 524 of the angled via 520 has an oval shape along the first surface 514 or second surface, the solder pad 536 can be circular to accommodate electrical coupling with the die interconnect or the board interconnect.

In a further example, the interposer 506 can include one or more routing layers along the first surface 514 or the second surface (e.g., the first surface 214 and the second surface 216 as shown in the example of FIG. 2). The one or more routing layers can be electrically coupled to at least one angled via 520 at the first end 522 or the second end 524. In an example, the one or more routing layers can be electrically coupled to the solder pad 536. Accordingly, additional signal routing can be provided on the first surface 514 or the second surface of the interposer 506.

The longitudinal axis 526 of the angled via 520 can be disposed at an angle from the x-axis 528 or y-axis 530. In the example of FIG. 5, the longitudinal axis 526 is disposed at an angle B from the x-axis 528. Forming the aperture 540 using a laser can include adjusting one or more of the angle A (e.g., angle A as shown in FIG. 2 and described herein), angle B, a relative position of the laser with respect to the interposer, or a combination thereof. Accordingly, the laser can follow a profile to generate the aperture 540, such as an aperture 540 having the desired shape and size of the first end and the second end.

FIG. 6 is block diagram of an exemplary method 600 for making an interposer having at least one angled via, such as the interposer previously described in the examples herein and shown for instance in FIGS. 1-5. In describing the method 600, reference is made to one or more components, features, functions, and processes previously described herein. Where convenient, reference is made to the components, features, processes and the like with reference numerals. Reference numerals provided are exemplary and are nonexclusive. For instance, features, components, functions, processes, and the like described in the method 600 include, but are not limited to, the corresponding numbered elements provided herein. Other corresponding features described herein (both numbered and unnumbered) as well as their equivalents are also considered.

At 602, an aperture can be formed between a first surface and a second surface of a dielectric layer (e.g., the dielectric layer 212, 312, or 512 as previously described herein). In some examples, the dielectric layer can be a single dielectric layer. The dielectric layer can include a normal axis (e.g., normal axis 218 as shown in the example of FIG. 2) that is perpendicular to the first or second surface, such as the first surface (e.g., 214, 314, or 414 as shown and described herein) or the second surface (216, 316, or 416 as shown and described herein). The aperture can include a first end at the first surface and a second end at the second surface.

A longitudinal axis of the aperture can extend through a center of the first end and a center of the second end of the aperture. The longitudinal axis can be disposed at an angle (e.g., angle A as shown in the example of FIG. 2 as described herein) from the normal axis, an angle (e.g., angle B from an x-axis or y-axis as shown in the example of FIG. 5 and described herein), or a combination thereof. For instance, the longitudinal axis can be disposed at a non-zero angle from the normal axis, such as angle between 1 and 89 degrees from the normal axis. The aperture can be linear (e.g., along the longitudinal axis) between the first surface and the second surface (or the first end and the second end). The difference between the location of the first end and the second end along the first and second surface respectively can be based on the angle of the longitudinal from the normal axis.

In various examples, the cross-sectional dimension of the first end or the second end of the aperture perpendicular to the longitudinal axis can include, but is not limited to, 5 μm, 500 μm, or a value therebetween. For instance, where the aperture includes a circular cross-sectional shape perpendicular to the longitudinal axis, the aperture can have a diameter of 5 μm, 500 μm, or a value therebetween.

In some examples, the aperture can be formed by a laser, such as an excimer, carbon monoxide, carbon dioxide, yttrium aluminium garnet (YAG) laser, or other type of laser capable of removing material from the dielectric layer. The laser can be operated in a continuous wave, pulsed, repetitively pulsed, mode locked operation, or the like. In an example, the laser can be aligned at a position and angle to form the aperture along the longitudinal axis. In other examples, the laser can be combined with one or more beam steering elements, such as a laser scanning system. For instance, the laser scanning system can include a galvanometer operatively coupled with a scanning mirror or lens. The laser steering element can position the laser beam to form the aperture having the location of the first end and the second end along the longitudinal axis. In other examples, the aperture can be formed by mechanical drilling, water drilling, or other aperture forming process.

In some examples, a profile can be used to form the aperture. For instance, the position of the drill bit, water jet, or laser beam can follow the profile to generate an aperture having the size and shape of the first end and the second end along the first and second surface. For instance, the profile can be used to form an aperture having a larger cross-sectional dimension than the drill bit, water jet, or laser beam. In other examples, the profile can be used to form a shape, such as a circular, oval, or other shape of the first end and the second end.

The size and shape of the first end can be different than the size (e.g., cross-sectional dimension) and shape of the second end. In an example, the dimension of the second end along the second surface can be equal to the dimension of the first end along the first surface. In other examples, the dimension of the second end along the second surface can be 1.1, 1.25, 1.5, 2 times larger than dimension, or any value therebetween, or the other way around. In further examples, the dimension can be between 1.25 and 5 times larger than the dimension, or vice versa. In some examples, the dimension of the second end can be up to 25 times larger than the dimension of the first end, or the other way around. Accordingly, the angled via that is located therein can include a first end having a different dimension (e.g., smaller) than the second end for coupling the angled via between different sized or shaped interconnects. In other examples, the aperture can be formed with a non-circular cross-sectional shape to generate a circular aperture along the first surface and the second surface. The non-circular shape can account for perspective of the cross-sectional shape that is projected along the first and second surface based on the angle of the longitudinal axis with respect to the normal axis. For instance, a circular cross-sectional shape can form an oval shape along the first or second surface where the longitudinal angle is disposed at a non-zero angle with respect to the normal axis. The profile can compensate for the projected shape to form the shape of the first end or the second end of the aperture. In other words, the profile can be used to generate a circular or any other desired shape along the first or second surface despite the angle of the longitudinal axis. In further examples, the angled via can have a conical shape to adapt the smaller diameter of the first end to the larger diameter of the second end. In other examples, the angled via can include an hourglass shape with the diameters of the first end and the second end being larger than the smallest diameter of the angled via.

In further examples, a plurality of apertures can be formed in the interposer. For instance, the first ends of the respective plurality of apertures can be arranged in a first pattern along the first surface and the second ends of the respective apertures can be arranged in a second pattern along the second surface. In some examples, the first pattern or the second pattern can include, but are not limited to, a grid, circular pattern, staggered pattern, diamond pattern, irregular patterns, or other arrangements. The angle of the respective longitudinal axes of the plurality of angled vias can be different to form apertures having a first pitch at the first ends and a second pitch at the second ends. For instance, a longitudinal axis of at least one of the angled vias disposed at a different angle from the normal axis than the longitudinal axes of the other angled vias. The pitch between at least two of the first ends can be different than the pitch of the second ends. For instance, in some examples, each of the first ends can have a first pitch and each of the second ends can have a second pitch that is different than the first pitch. The pitch can include, but is not limited to, one-and-one-half times the cross-sectional dimension of the first end or the second end. In other examples, the angles of the respective angled vias can increase or decrease from the apertures located at the center of the interposer toward the perimeter of the interposer.

At 604, a conductive material can be disposed within the aperture to form an angled via, such as the angled via 220, 320, 420, or 520 as shown in the examples of FIGS. 2-5 and described herein. Disposing the conductive material within the aperture can include forming a first end of the angled via to be coplanar with the first surface and a second end of the angled via to be coplanar with the second surface. The conductive material can be disposed within the aperture by a process including, but not limited to, electroless deposition, vacuum assisted deposition (of, e.g., printed filler material), electroplating, chemical vapor deposition, sputtering, or other conductive material deposition process. In some examples, the conductive material can include, but is not limited to, copper, nickel, tin, silver, gold, lead, palladium, molybdenum, tungsten, titanium nitride, bismuth, or combinations thereof. Accordingly, the angled via can be formed having a first end located along the first surface and a second end located along the second surface, where the longitudinal axis is extended between the first end and the second end and is disposed at an angle from the normal axis.

In other examples, one or more interconnects can be electrically coupled to the first end or the second end of the angled via. For instance, a die interconnect (e.g., die interconnect 108) or a board interconnect (e.g., a board interconnect 110) can be electrically coupled to the angled vias. The interconnects can be attached to the angled vias using solder, electrically conductive adhesive, wire bonding, electroless deposition, electroplating, chemical vapor deposition, vacuum deposition, or other electrical coupling process. In an example, the first end of the angled via can be coupled to a different sized or shaped interconnect than is coupled to the second end.

In further examples, at least one secondary dielectric layer can be disposed along the first or second surface of the dielectric layer. The secondary dielectric layer can be a solder mask or a dielectric layer for insulating one or more routing layers disposed along the first surface or the second surface. In other examples, the secondary dielectric layer can include at least one angled via to form an interposer having two or more layers of angled vias.

In some instances, a solder pad can be electrically coupled to the first end or the second end of the angled via. In various examples, the solder pad can include the same size or shape as the respective first or second end, or in other examples, the solder pad can include a different size or shape than the respective first end or second end to which it is coupled. For instance, the angled via can include an oval shape along the first surface or the second surface and the solder pad can include a circular shape. The solder pad can be electrically coupled to the angled via using electroless deposition, electroplating, sputtering, chemical vapor deposition, vacuum deposition, or the like. The solder pad can provide mechanical stability for electrically and mechanically coupling an interconnect to the angled via, and in some instances, the solder pad can reduce corrosion of the conductive material of the angled via.

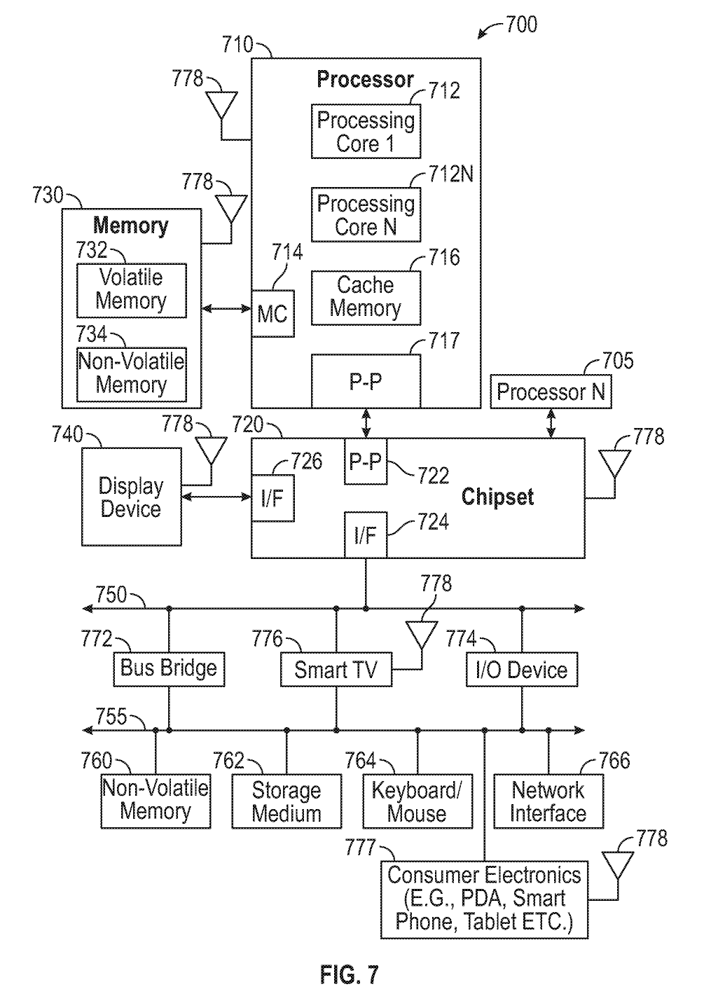

FIG. 7 is a block diagram illustrating an example machine 700 (electronic device) upon which any one or more of the devices (e.g., electronic device 100 including the die 102 and the one or more of the interposers 106, 206, 306, 406, or 506) or techniques discussed herein may perform. In alternative embodiments, the machine 700 may operate as a standalone electronic device or may be connected (e.g., networked) to other machines. The machine 700 may be a personal computer (PC), a tablet PC, a set-top box (STB), a Personal Digital Assistant (PDA), a mobile telephone, a web appliance, a network router, switch or bridge, watch, smartwatch, smart home system, internet-of-things device, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate on, logic or a number of components, modules, or mechanisms. Modules are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The machine (e.g., computer, or computer system) 700 may include a hardware processor 702 (e.g., a CPU, GPU, a hardware processor core, or any combination thereof), a main memory 704, and a static memory 706, some or all of which may communicate with each other via an interlink (e.g., bus) 708. The machine 700 may further include a display device 710, an alphanumeric input device 712 (e.g., a keyboard), and a user interface (UI) navigation device 714 (e.g., a mouse). In an example, the display device 710, input device 712 and UI navigation device 714 may be a touch screen display. The machine 700 may additionally include a mass storage device (e.g., drive unit) 716, a signal generation device 718 (e.g., a speaker), a network interface device 720, and one or more sensors 721, such as a global positioning system (GPS) sensor, compass, accelerometer, or other sensor. The machine 700 may include an output controller 728, such as a serial (e.g., universal serial bus (USB), parallel, or other wired or wireless (e.g., infrared (IR)) connection to communicate or control one or more peripheral devices (e.g., a printer, card reader, etc.).

The mass storage device 726 may include a machine readable medium 722 on which is stored one or more sets of data structures or instructions 724 (e.g., software) embodying or utilized by any one or more of the techniques or functions described herein. The instructions 724 may also reside, completely or at least partially, within the main memory 704, within static memory 706, or within the hardware processor 702 during execution thereof by the machine 700. In an example, one or any combination of the hardware processor 702, the main memory 704, the static memory 706, or the mass storage device 716 may constitute machine readable media.

While the machine readable medium 722 is illustrated as a single medium, the term “machine readable medium” may include a single medium or multiple media (e.g., a centralized or distributed database, and/or associated caches and servers) that arranged to store the one or more instructions 724.

The term “machine readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine readable medium examples may include solid-state memories, and optical and magnetic media. In an example, a massed machine-readable medium comprises a machine-readable medium with a plurality of particles having resting mass. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 724 may further be transmitted or received (e.g., transceived) over a communications network 726 using a transmission medium via the network interface device 720 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 602.11 family of standards known as Wi-Fi®, IEEE 602.16 family of standards known as WiMAX®), peer-to-peer (P2P) networks, among others. In an example, the network interface device 720 may include one or more physical jacks (e.g., Ethernet, coaxial, or phone jacks) or one or more antennas to connect to the communications network 726. In an example, the network interface device 720 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 700, and includes digital or analog communications signals or other intangible medium to facilitate communication of such software.

### VARIOUS NOTES & EXAMPLES

Each of these non-limiting examples may stand on its own, or may be combined in various permutations or combinations with one or more of the other examples. To better illustrate the method and apparatuses disclosed herein, a non-limiting list of embodiments is provided here:

Example 1 is an interposer for an electronic package, the interposer comprising: a dielectric layer including a first surface and a second surface, wherein the dielectric layer includes a normal axis perpendicular with the first or second surface; an angled via, the angled via including: a first end located along the first surface and a second end located along the second surface; and a longitudinal axis extended between the first end and the second end, wherein the longitudinal axis is disposed at an angle from the normal axis.

In Example 2, the subject matter of Example 1 optionally includes wherein the dielectric layer is a single layer.

In Example 3, the subject matter of any one or more of Examples 1-2 optionally include wherein the angle is greater than zero, but less than ninety degrees.

In Example 4, the subject matter of any one or more of Examples 1-3 optionally include wherein a cross-sectional dimension of the first end along the first surface is different than a cross-sectional dimension of the second end along the second surface, and wherein the cross-sectional dimension of the second end is at least one-and-one-half times larger than the cross-sectional dimension of the first end.

In Example 5, the subject matter of any one or more of Examples 1-4 optionally include wherein the first end and the second end are oval shaped along the first surface and the second surface respectively.

In Example 6, the subject matter of Example 5 optionally includes a solder pad electrically coupled on the first end or the second end, wherein a shape of the solder pad is circular or rectangular.

In Example 7, the subject matter of any one or more of Examples 1-6 optionally include wherein the interposer includes a plurality of angled vias including a first angled via and a second angled via, each of the angled vias include respective longitudinal axes that are disposed at different angles from the normal axis.

In Example 8, the subject matter of Example 7 optionally includes wherein a pitch between at least two of the plurality of first ends is different than a pitch between at least two of the plurality of second ends.

In Example 9, the subject matter of Example 8 optionally includes wherein the plurality of first ends are arranged in a first pattern, and the plurality of second ends are arranged in a second pattern, the first pattern being different than the second pattern.

In Example 10, the subject matter of any one or more of Examples 1-9 optionally include wherein the angles of the respective longitudinal axes progressively increase or decrease between the center and the periphery of the interposer.

In Example 11, the subject matter of any one or more of Examples 1-10 optionally include wherein a size and shape of the first end is different than a size or shape of the second end.

Example 12 is a method of making an interposer including at least one angled via, the method comprising: forming an aperture between a first surface and a second surface of a dielectric layer, wherein the dielectric layer includes a normal axis perpendicular to the first or second surface, and the aperture includes a longitudinal axis disposed at an angle from the normal axis; and disposing a conductive material within the aperture to form an angled via.

In Example 13, the subject matter of Example 12 optionally includes wherein forming the aperture includes forming the aperture having a cross-sectional dimension of the second end that is at least fifty-percent larger than a cross-sectional dimension of the first end.

In Example 14, the subject matter of any one or more of Examples 12-13 optionally include wherein a difference between a location of the first end and a location of the second end with respect to the normal axis is based on the angle.

In Example 15, the subject matter of any one or more of Examples 12-14 optionally include wherein forming the aperture includes forming the aperture wherein a cross-sectional shape of the first end is different than a cross-sectional shape of the second end.

In Example 16, the subject matter of any one or more of Examples 12-15 optionally include wherein forming the aperture includes forming the aperture wherein a shape of the first end along the first surface is different than a shape of the second end along the second surface.

In Example 17, the subject matter of any one or more of Examples 12-16 optionally include wherein forming the aperture includes forming the aperture using a laser beam, and wherein the laser beam follows a profile to form the aperture, the aperture having a non-circular cross-sectional shape perpendicular to the longitudinal axis to generate a circular aperture along the first surface or the second surface.

In Example 18, the subject matter of any one or more of Examples 12-17 optionally include wherein forming the aperture includes forming a plurality of apertures and a plurality of angled vias disposed therein, a longitudinal axis of a first angled via is disposed at a different angle from the normal axis than a longitudinal axis of a second angled via.

In Example 19, the subject matter of Example 18 optionally includes wherein the angles of the respective longitudinal axes progressively increase or decrease between a center and a periphery of the interposer.

In Example 20, the subject matter of any one or more of Examples 18-19 optionally include wherein forming the plurality of apertures and disposing the conductive material within the plurality of apertures includes arranging the plurality of first ends in a first pattern and arranging the plurality of second ends in a second pattern, wherein the first pattern includes a first pitch between two or more of the first ends and the second pattern includes a second pitch between two or more of the second ends.

In Example 21, the subject matter of Example 20 optionally includes wherein the first pattern is different than the second pattern.

In Example 22, the subject matter of any one or more of Examples 20-21 optionally include a plurality of interconnects electrically coupled to the plurality of first ends and the plurality of second ends.

In Example 23, the subject matter of any one or more of Examples 12-22 optionally include wherein disposing the conductive material within the aperture includes forming a first end of the angled via to be coplanar with the first surface and a second end of the angled via to be coplanar with the second surface.

Example 24 is a system including an interposer having at least one angled via, the system comprising: an interposer including: a dielectric layer having a first surface and a second surface, wherein the dielectric layer includes a normal axis perpendicular to the first or second surface; an angled via, the angled via including: a first end located along the first surface and a second end located along the second surface; a longitudinal axis extended between the first end and the second end, wherein the longitudinal axis is disposed at an angle from the normal axis; a die electrically coupled to the first end with a first interconnect; and a circuit board electrically coupled to the second end with a second interconnect.

In Example 25, the subject matter of Example 24 optionally includes wherein the plurality of angled vias extend linearly between the first interconnect and the second interconnect.

In Example 26, the subject matter of any one or more of Examples 24-25 optionally include wherein the dielectric layer is a single layer.

In Example 27, the subject matter of any one or more of Examples 24-26 optionally include wherein the angle is greater than zero, but less than ninety degrees.

In Example 28, the subject matter of any one or more of Examples 24-27 optionally include wherein a cross-sectional dimension of the first end is different than a cross-sectional dimension of the second end, and the cross-sectional dimension of the second end is at least one-and-one-half times larger than the cross-sectional dimension of the first end.

In Example 29, the subject matter of any one or more of Examples 24-28 optionally include wherein the first end and the second end are oval shaped along the first surface and the second surface respectively.

In Example 30, the subject matter of Example 29 optionally includes a solder pad electrically coupled on the first end or the second end, wherein a shape of the solder pad is circular or rectangular.

In Example 31, the subject matter of any one or more of Examples 24-30 optionally include wherein the interposer includes a plurality of angled vias including a first angled via and a second angled via, each of the angled vias includes a respective longitudinal axis that is disposed at a different angle from the normal axis.

In Example 32, the subject matter of Example 31 optionally includes wherein a pitch between at least two of the plurality of first ends is different than a pitch between at least two of the plurality of second ends.

In Example 33, the subject matter of Example 32 optionally includes wherein the angles of the respective longitudinal axes progressively increase or decrease between the center and the periphery of the interposer.

In Example 34, the subject matter of any one or more of Examples 32-33 optionally include wherein the plurality of first ends are arranged in a first pattern and the plurality of second ends are arranged in a second pattern, the first pattern being different than the second pattern.

In Example 35, the subject matter of any one or more of Examples 24-34 optionally include wherein a size and shape of the first end is different than a size or shape of the second end.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An interposer for an electronic package, the interposer comprising:
a dielectric layer including a first surface and a second surface opposite the first surface, wherein the dielectric layer includes a normal axis perpendicular with the first or second surface;
an angled via, the angled via including:
a first end located along the first surface and a second end located along the second surface; and
a longitudinal axis extended between the first end and the second end, wherein the longitudinal axis is disposed at an angle from the normal axis, wherein a cross-sectional dimension of the first end along the first surface is the same as the cross-sectional dimension of the second end along the second surface.

2. The interposer of claim 1, wherein the dielectric layer is a single layer.

3. The interposer of claim 1, wherein the angle is greater than zero, but less than ninety degrees.

4. (canceled)

5. The interposer of claim 1, wherein the first end and the second end are oval shaped along the first surface and the second surface respectively.

6. The interposer of claim 5, further comprising a solder pad electrically coupled on the first end or the second end, wherein a shape of the solder pad is circular or rectangular.

7. The interposer of claim 1, wherein the interposer includes a plurality of angled vias including a first angled via and a second angled via, the first and second angled vias include respective longitudinal axes that are disposed at different angles from the normal axis.

8. The interposer of claim 7, wherein a pitch between at least two of the plurality of first ends is different than a pitch between at least two of the plurality of second ends.

9. The interposer of claim 8, wherein the plurality of first ends are arranged in a first pattern, and the plurality of second ends are arranged in a second pattern, the first pattern being different than the second pattern, the first pattern including an irregular pattern and the second pattern including a grid pattern.

10. The interposer of claim 1, wherein the angles of the respective longitudinal axes progressively increase or decrease between the center and the periphery of the interposer.

11. The interposer of claim 1, wherein a size and shape of the first end is different than a size and shape of the second end.

12-15. (canceled)

16. A system including an interposer having at least one angled via, the system comprising:
an interposer including:
a dielectric layer having a first surface and a second surface opposite the first surface, wherein the dielectric layer includes a normal axis perpendicular to the first or second surface;
an angled via, the angled via including:
a first end located along the first surface and a second end located along the second surface;
a longitudinal axis extended between the first end and the second end, wherein the longitudinal axis is disposed at an angle from the normal axis, wherein a cross-sectional dimension of the first end along the first surface is the same as the cross-sectional dimensional of the second end along the second surface;
a die electrically coupled to the first end with a first interconnect; and
a circuit board electrically coupled to the second end with a second interconnect.

17. The system of claim 16, wherein the plurality of angled vias extend linearly between the first interconnect and the second interconnect.

18. The system of claim 16, wherein the dielectric layer is a single layer.

19. The system of claim 16, wherein the interposer includes a plurality of angled vias including a first angled via and a second angled via, each of the angled vias includes a respective longitudinal axis that is disposed at a different angle from the normal axis.

20. The system of claim 19, wherein a pitch between at least two of the plurality of first ends is different than a pitch between at least two of the plurality of second ends.

21. The system of claim 20, wherein the plurality of first ends are arranged in a first pattern and the plurality of second ends are arranged in a second pattern, the first pattern being different than the second pattern, the first pattern including an irregular pattern and the second pattern including a grid pattern.
